(19) United States
(12) Patent Application Publication
(10) Pub. No.: US 2012/0001275 A1
(43) Pub. Date: Jan. 5, 2012

(54) SEMICONDUCTOR DEVICE

(75) Inventors: Dahe CHI, Osaka (JP); Seishi OIDA, Kyoto (JP)

(73) Assignee: PANASONIC CORPORATION, Osaka (JP)

(21) Appl. No.: 13/228,777

(22) Filed: Sep. 9, 2011

Related U.S. Application Data
(63) Continuation of application No. PCT/JP2010/001015, filed on Feb. 18, 2010.

(30) Foreign Application Priority Data
Mar. 16, 2009 (JP) 2009-063611

(51) Int. Cl. H01L 29/84; H01L 21/52

(52) U.S. Cl. 257/415; 438/51; 257/E29.324; 257/E21.5

(57) ABSTRACT

A semiconductor device in which intrusion of the cutting water and cutting wastes in the singulation process can be prevented, and reliability is improved includes: a substrate; at least one semiconductor element having a piezoelectric conversion function and mounted on the main surface of the substrate; a casing fixed to the main surface of the substrate to cover the semiconductor element; a through hole formed in the substrate or the casing; and a predetermined substance filled into the through hole to close the through hole, wherein the predetermined substance has properties such that the predetermined substance wettably spreads by heating to open the through hole.

### CROSS REFERENCE TO RELATED APPLICATION

This is a continuation application of PCT application No. PCT/JP2010/001015 filed on Feb. 18, 2010, designating the United States of America.

### BACKGROUND OF THE INVENTION

(1) Field of the Invention

The present invention relates to semiconductor devices, and particularly relates to semiconductor devices formed using an MEMS (Micro Electro Mechanical Systems) technique.

(2) Description of the Related Art

For example, semiconductor devices using an electret condenser having a vibrating electrode exist. Usually, such a semiconductor device has a structure in which an MEMS semiconductor element and a CMOS (Complementary Metal Oxide Semiconductor) semiconductor element are mounted on a substrate, and are covered with a casing. In the semiconductor device, a sound wave enters an inside of the semiconductor device through a hole formed in the substrate or the casing, and is converted into an electric signal by a diaphragm structure of the MEMS semiconductor element, and output.

Manufacturing of the semiconductor device is performed as follows: a plurality of semiconductor devices are formed at the same time, and individually separated to be singulated. The separation here is performed by dicing or a process method of cutting with a metal mold.

In the dicing, usually, a circular dicing saw having particles of diamond or CBN (cubic boron nitride) fixed thereto is rotated at a high speed for dicing. In the dicing, cutting water for removing dicing wastes and suppressing frictional heat is flowed while the dicing saw is rotated at a high speed for dicing. The diaphragm structure and beam structure that the MEMS semiconductor element has are a fragile structure, however. For this, those structures may be destroyed by undesirable intrusion of the cutting water from a sound hole. Particularly, the size of electric components has been reduced while the density in the mounting is increased, and the undesirable intrusion of the cutting water into the sound hole increasingly causes problems in the dicing.

On the other hand, in the process method of cutting with a metal mold, cutting wastes are scattered. The scattered cutting wastes may intrude into a place in the vicinity of the sound hole or the inside of the sound hole, and affect vibration of the diaphragm structure to give an influence on sound quality.

Contrary to that, disclosed is a silicon condenser microphone 600 including a substrate on which a microphone chip and an application specific integrated circuit (ASIC) chip are mounted, and a metallic casing 610 for covering the substrate, wherein a first sound hole 610a or a second sound hole 620a is formed on the metallic casing 610 or substrate as an acoustic hole (see Japanese Unexamined Patent Application Publication No. 2007-82233.), as shown in FIG. 18. In the silicon condenser microphone 600, a connection pattern 621 for bonding the metallic casing 610 is formed, and an adhesive 630 for bonding the metallic casing 610 to the substrate is provided on the connection pattern 621.

### SUMMARY OF THE INVENTION

In the structure disclosed in Japanese Unexamined Patent Application Publication No. 2007-82233, however, the cutting water for removing dicing wastes and suppressing frictional heat, which is used in the dicing, may undesirably intrude into the first sound hole 610a or the second sound hole 620a to destroy the diaphragm structure or beam structure of the MEMS microphone semiconductor element.

Similarly, in the process method of cutting with a metal mold, the produced cutting wastes may undesirably intrude into the first sound hole 610a or the second sound hole 620a and affect vibration of the diaphragm structure to give an influence on the sound quality.

Accordingly, in order to solve the problems, an object of the present invention is to provide a semiconductor device in which intrusion of cutting water and cutting wastes in the singulation process can be prevented, and reliability is improved.

In order to achieve the object above, a semiconductor device according to the present invention includes: a substrate; at least one semiconductor element having a piezoelectric conversion function and mounted on a main surface of the substrate; a casing fixed to the main surface of the substrate to cover the semiconductor element; a through hole formed in one of the substrate and the casing; and a predetermined substance filled into the through hole to close the through hole, wherein the predetermined substance has properties such that the predetermined substance wettably spreads by heating to open the through hole.

A semiconductor device according to the present invention may include: a substrate; at least one semiconductor element having a piezoelectric conversion function and mounted on a main surface of the substrate; a casing fixed to the main surface of the substrate to cover the semiconductor element; a through hole formed in one of the substrate and the casing; and a predetermined substance wettably spread on the through hole or the substrate to open the through hole, wherein the predetermined substance has properties such that the predetermined substance wettably spreads by heating.

Here, the predetermined substance preferably has a melting point less than 220° C., a softening temperature less than 220° C., or a volatilizing temperature less than 220° C.

According to such a configuration, a substance having a melting point lower than that of the solder is filled into the through hole formed in the substrate or the casing, and therefore no cutting wastes and cutting water during the separation for singulation of the semiconductor device 500 enter the through hole. Moreover, for example, the substance provided within the through hole is molten by a heat treatment such as mounting on the mother substrate after the separation to wettably spread around the through hole. Thereby, the through hole is opened. Thereby, a semiconductor device can be provided in which intrusion of the cutting water and cutting wastes in the singulation process can be prevented, and reliability is improved.

In order to achieve the object above, a semiconductor device according to the present invention may include: a substrate; at least one semiconductor element having a piezoelectric conversion function and mounted on the main surface of the substrate; a casing fixed to the main surface of the substrate to cover the semiconductor element; and a through hole formed in one of the substrate and the casing, wherein a moisture absorbable substance having moisture absorbing properties is provided on an inner wall of the through hole.

According to the configuration, a highly moisture absorbable substance is provided on the inner wall of the through hole provided in the substrate or the casing. Accordingly, when separation by the dicing is performed for singulation of the semiconductor device, the cutting water can adhere to the inner wall of the through hole. Thereby, for example, the semiconductor element having a diaphragm structure is protected, and a highly reliable semiconductor device can be provided.

In order to achieve the object above, a semiconductor device according to the present invention may include: a substrate; at least one semiconductor element having a piezoelectric conversion function and mounted on the main surface of the substrate; a casing fixed to the main surface of the substrate to cover the semiconductor element; and an adhesive applied to the substrate to fix the substrate to the casing in close contact and seal the semiconductor element; wherein part of the adhesive is opened by heating.

According to the configuration, a through hole is formed in the adhesive for fixing the casing by the heat when the substrate is mounted on the mother substrate, for example. Accordingly, no other through hole needs to be provided in the substrate or the casing in advance. Moreover, the semiconductor device is sealed when the semiconductor devices are separated for singulation. For this reason, no cutting wastes and cutting water to be produced in the separation process enter the through hole. Thus, a semiconductor device can be provided in which intrusion of the cutting water and cutting wastes in the singulation process can be prevented, and reliability is improved.

In order to achieve the object above, a semiconductor device according to the present invention may include: a substrate; at least one semiconductor element having a piezoelectric conversion function and mounted on the main surface of the substrate; a casing fixed to the main surface of the substrate to cover the semiconductor element; an adhesive applied to a periphery of a region of the main surface on which the semiconductor element is mounted, to fix the casing to the substrate in close contact; and a dam having a height greater than a thickness of the adhesive and formed between the semiconductor element and the adhesive on the main surface of the substrate, wherein at least one gap without the adhesive is provided in part of the periphery of the region to which the adhesive is applied, the dam is formed between the at least one gap and the semiconductor element, and the gap is configured to serve as a through hole after the substrate is fixed to the casing.

According to the configuration, the gap without the adhesive is formed in advance in part of the region of the adhesive applied to the substrate to fix the casing, and the dam is formed on the substrate. Thereby, no through hole needs to be provided in the substrate or the casing in advance, and no cutting water to be produced in the dicing process enters the semiconductor device. Thus, a semiconductor device can be provided in which intrusion of the cutting water and cutting wastes in the singulation process can be prevented, and reliability is improved.

In order to achieve the object above, a semiconductor device according to the present invention may include: a substrate; at least one semiconductor element having a piezoelectric conversion function and mounted on the main surface of the substrate; a rib fixed to the main surface of the substrate so as to surround the semiconductor element; a plate cap that is a flat plate, and is fixed to the rib so as to cover the semiconductor element; a through hole formed in the substrate or the plate cap; and a predetermined substance filled into the through hole to close the through hole, wherein the predetermined substance has properties such that the predetermined substance wettably spreads by heating to open the through hole.

According to such a configuration, a substance having a melting point lower than that of the solder is filled into the through hole formed in the substrate or the plate cap, and therefore no cutting wastes and cutting water during the separation for singulation of the semiconductor device enter the through hole. Moreover, for example, the substance provided within the through hole is molten by a heat treatment such as mounting on the mother substrate after the separation to wettably spread around the through hole. Thereby, the through hole is opened. Thereby, a semiconductor device can be provided in which intrusion of the cutting water and cutting wastes in the singulation process can be prevented, and reliability is improved.

The present invention can provide a semiconductor device in which intrusion of cutting water and cutting wastes in the singulation process can be prevented, and reliability is improved.

### Further Information About Technical Background To This Application

The disclosure of Japanese Patent Application No. 2009-063611 filed on Mar. 16, 2009 including specification, drawings and claims is incorporated herein by reference in its entirety.

The disclosure of PCT application No. PCT/JP2010/001015 filed on Feb. 18, 2010, including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a sectional view of a semiconductor device according to Embodiment 1;

FIG. 2 is a sectional view of a mounted body on which the semiconductor device according to Embodiment 1 is mounted;

FIG. 3 is a sectional view of a semiconductor device according to Modification 1 of Embodiment 1;

FIG. 4 is a sectional view of a mounted body on which the semiconductor device according to Modification 1 of Embodiment 1 is mounted;

FIG. 5 is a sectional view of a semiconductor device according to Modification 2 of Embodiment 1;

FIG. 6 is a sectional view of a mounted body on which the semiconductor device according to Modification 2 of Embodiment 1 is mounted;

FIG. 7 is a sectional view of a semiconductor device according to Embodiment 2;

FIG. 8 is a sectional view of a semiconductor device according to Embodiment 3;

FIG. 9 is a sectional view of a mounted body on which the semiconductor device according to Embodiment 3 is mounted;

FIG. 10 is a top view of a semiconductor device according to Embodiment 4;

FIG. 11 is a sectional view of a semiconductor device according to Embodiment 4;

FIG. 12 is a sectional view of a semiconductor device according to Embodiment 5;

FIG. 13 is a sectional view of a mounted body on which the semiconductor device according to Embodiment 5 is mounted;

FIGS. 14A to 14E are drawings for illustrating a method for manufacturing a semiconductor device according to Embodiment 5;

FIG. 15 is a sectional view of a semiconductor device according to Modification of Embodiment 5;

FIG. 16 is a sectional view of a mounted body on which the semiconductor device according to Modification of Embodiment 5;

FIG. 17 is an example of a sectional view of a mounted body on which a semiconductor device having a substance wettably spreadable into a through hole is mounted; and

FIG. 18 is a sectional view showing the conventional semiconductor device.

### DESCRIPTION OF THE PREFERRED EMBODIMENTS

Hereinafter, embodiments of the present invention will be described with reference to the drawings.

### Embodiment 1

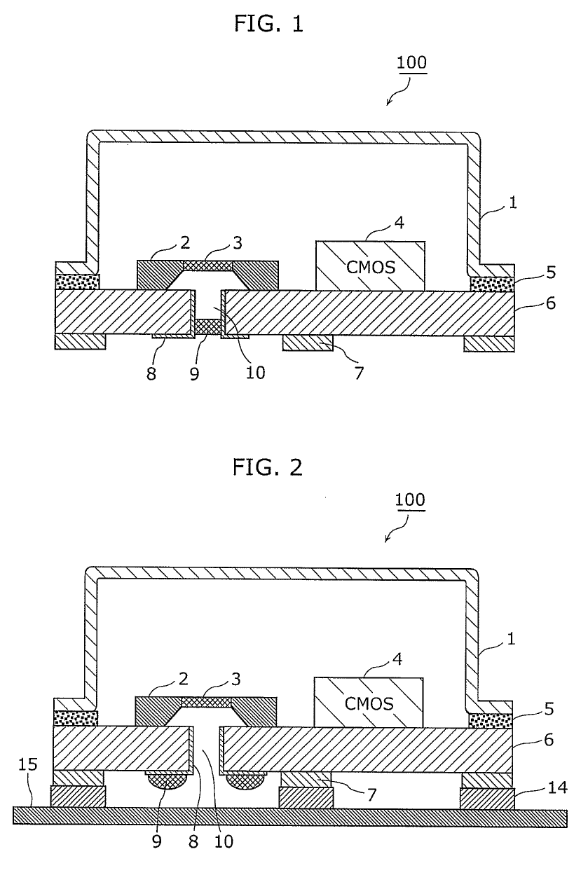

FIG. 1 is a sectional view of a semiconductor device according to Embodiment 1.

As shown in FIG. 1, a semiconductor device 100 includes a casing 1, a semiconductor element 2, a semiconductor element 4, an adhesive 5, a substrate 6, and an electrode 7.

The casing 1 covers the semiconductor element 2 and semiconductor element 4 fixed to the substrate 6, and is fixed to the substrate 6 by the adhesive 5. The portion of the casing 1 connected to the substrate 6 by the adhesive 5 is curved in the same direction as that of the semiconductor element 2 or in the direction opposite to that of the semiconductor element 2.

The casing 1 may be formed with any material having high heat resistance. For example, the material of the casing 1 may be a metal such as Cu, Al, or Mg, or a non-metal such as plastics or ceramics, and is not particularly limited. In the case where the material of the casing 1 is a non-metal, the surface of the casing 1 is desirably Sn- or Ni-plated.

The semiconductor element 2 is a semiconductor element having a piezoelectric conversion function, for example, an MEMS microphone semiconductor element having a diaphragm structure 3 or a beam structure. The semiconductor element 2 is fixed to the substrate 6.

The semiconductor element 4 is a CMOS semiconductor element, and is fixed to the substrate 6. The semiconductor element 4 is, for example, a CMOS semiconductor element used for analog ICs, logic ICs, and memory ICs, but not particularly limited to those.

The adhesive 5 fixes the casing 1 to the substrate 6. The adhesive is composed of one of conductive epoxy resins, non-conductive epoxy resins, silver pastes, silicone resins, urethane resins, acrylic resins, and solder pastes, for example.

The substrate 6 is an epoxy glass cloth laminated substrate (glass-epoxy substrate), a polyimide glass cloth laminated substrate, or an aramide nonwoven fabric substrate, for example.

The substrate 6 has the semiconductor element 2 and semiconductor element 4 fixed to the main surface thereof. The casing 1 is fixed by the adhesive 5 so as to cover the fixed semiconductor element 2 and the semiconductor element 4.

The substrate 6 is provided with a through hole 10 serving as a sound hole, for example. A plated layer 8 is formed on the inner wall of the through hole 10 and around the through hole 10 on the surface opposite to the main surface. The electrode 7 is formed on the surface opposite to the main surface of the substrate 6.

The plated layer 8 is formed on the inner wall of the through hole 10 and in the vicinity of the through hole 10 on the surface opposite to the main surface of the substrate 6. The plated layer 8 is Au/Ni-plated, for example. Preferably, the thickness of the plated layer 8 is not more than 1 μm, and the thickness of the Ni plating is not more than 15 μm.

The electrode 7 is an electrode of Cu, for example, and is formed on the surface opposite to the main surface (surface on which the semiconductor element 2 and the semiconductor element 4 are fixed). Desirably, the electrode 7 is surface treated by a water-soluble heat-resistant preflux or Au/Ni plating.

The through hole 10 is formed in the substrate 6. On the surface of the substrate in which the electrode 7 is formed, the through hole 10 is filled with a filling substance 9 having a melting point less than 220° C. such that the thickness of the filling substance 10 may be smaller than that of the substrate 6. Thereby, the through hole 10 is closed. The filling substance 9 is not limited to a substance having a melting point less than 220° C. For example, the substance may have any melting point not more than that of a solder, or may have a softening temperature less than 220° C. or a volatilizing temperature less than 220° C.

Thus, the semiconductor device 100 is configured.

Next, an aspect of a mounted body on which the semiconductor device 100 is mounted will be described using the drawing.

FIG. 2 is a sectional view of a mounted body on which the semiconductor device according to Embodiment 1 is mounted. Same reference numerals will be given to the same elements as those in FIG. 1, and detailed description thereof will be omitted.

A mother substrate 15 is an epoxy glass cloth laminated substrate (glass-epoxy substrate), a polyimide glass cloth laminated substrate, or an aramide nonwoven fabric substrate, for example. The semiconductor devices 100 simultaneously formed are separated by the dicing or the process method of cutting with a metal mold, and mounted on the mother substrate 15 through solder 14.

Here, as shown in FIG. 2, the filling substance 9 wettably spreads on the substrate 6 in the vicinity of the through hole 10 without contacting the mother substrate 15. Thereby, the through hole 10 is opened, and functions as a sound hole, for example.

This will be simply described. The through hole 10 is filled (closed) by filling the through hole with the filling substance 9 having a melting point less than 220° C. at a thickness smaller than that of the substrate 6. The filling substance 9 is molten by heating of the solder 14 when the semiconductor device 100 is mounted on the mother substrate 15, to wettably spread on the substrate 6 in the vicinity of the through hole 10. Thereby, the through hole 10 is opened, and functions as a sound hole. Here, the melting point of the filling substance 9 is not more than that of the solder 14.

As above, the semiconductor device 100 is mounted on the mother substrate 15 by the solder 14.

As described above, the semiconductor devices 100 simultaneously formed are separated or singulated by the dicing or the process method of cutting with a metal mold, and each mounted on the mother substrate 15 by the solder 14.

In the case where the semiconductor devices 100 simultaneously formed are separated by the process method of cutting with a metal mold, the through hole 10 provided in the substrate 6 is filled with the filling substance 9 to be closed. Accordingly, no cutting wastes enter the through hole 10. For this reason, there is no influence on vibration of the diaphragm or sound quality. After mounting, the filling substance 9 filled into the through hole 10 wettably spreads. Thereby, the through hole serving as a sound hole is opened, and a desired function is demonstrated.

On the other hand, in the case where the semiconductor device 100 simultaneously formed are separated by the dicing, the through hole 10 provided in the substrate 6 is filled with the filling substance 9 to be closed. Accordingly, no cutting water enters the through hole 10, and the diaphragm structure 3 can be protected. After mounting, the filling substance 9 that closes the through hole 10 wettably spreads. Thereby, the through hole is opened, and a desired function is demonstrated.

As above, Embodiment 1 can provide a semiconductor device in which intrusion of the cutting water and cutting wastes in the singulation process can be prevented, and reliability is improved.

The filling substance 9 wettably spreads at the time of mounting on the substrate in the vicinity of the through hole 10 as described above, but not limited to this. Any other manner of wettable spreading is allowed if the filling substance 9 wettably spreads without contacting the mother substrate 15, and as a result, the through hole 10 is opened, and a desired function is demonstrated. For example, a residue of the filling material may be left on part of the inner wall of the through hole 10.

The filling substance 9 may be composed of a component different from that of the plated layer 8, and may be the same component as that of the solder 14.

### Modification 1

In Modification 1, a semiconductor device 110 including a substrate according to other aspect than that of the semiconductor device 100 in Embodiment 1 will be described.

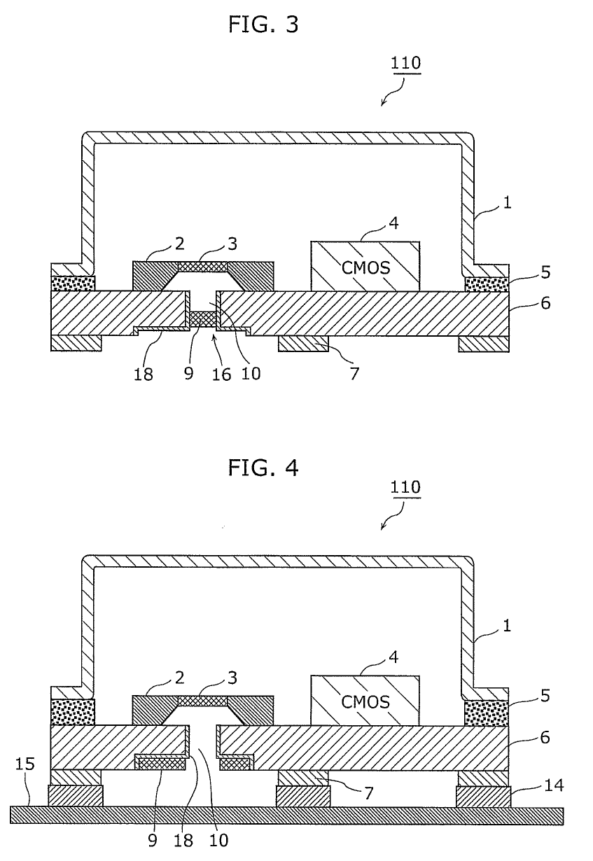

FIG. 3 is a sectional view of a semiconductor device according to Modification 1 of Embodiment 1. FIG. 4 is a sectional view of a mounted body on which the semiconductor device according to Modification 1 of Embodiment 1 is mounted. Same reference numerals will be given to the same elements as those in FIG. 1 or FIG. 2, and detailed description thereof will be omitted.

Unlike the semiconductor device 100, the semiconductor device 110 shown in FIG. 3 and FIG. 4 includes a substrate 6 having a depression 16.

The depression 16 is a depressed portion in the substrate provided on the vicinity of a through hole 10 on the surface opposite to the main surface of the substrate 6, i.e., the mounting surface for a mother substrate 15. A plated layer 18 is formed in the depression 16.

The plated layer 18 is formed on the inner wall of the through hole 10 and the depression 16 in the vicinity of the through hole 10 on the surface opposite to the main surface of the substrate 6.

As shown in FIG. 3, the through hole 10 is formed in the substrate 6. The through hole 10 is filled with a filling substance 9 having a melting point less than 220° C. in the same manner as in Embodiment 1 such that the thickness of the filling substance 9 may be smaller than that of the substrate. Thereby, the through hole 10 is closed on the side of the mounting surface for the mother substrate 15.

As shown in FIG. 4, the through hole 10 is filled (closed) by filling the through hole with the filling substance 9 at a thickness smaller than that of the substrate. The filling substance 9 is molten by heating of a solder 14 when the semiconductor device 110 is mounted on the mother substrate 15, to wettably spread on the depression 16 in the substrate 6 in the vicinity of the through hole 10. Thereby, the through hole 10 is opened.

Thus, the filling substance 9 wettably spreads on the depression 16 in the substrate 6 in the vicinity of the through hole 10 without contacting the mother substrate 15, as shown in FIG. 4.

Thus, the semiconductor device 110 is configured, and mounted on the mother substrate 15 by the solder 14.

As above, in Modification 1, the depression 16 is provided in the substrate 6. Thereby, when the semiconductor device 110 is mounted on the mother substrate 15, the filling substance 9 easily wettably spreads on the depression 16 without contacting the mother substrate 15, to open the through hole 10.

### Modification 2

In Embodiment 1 and Modification 1, examples of the semiconductor devices 100 and 110 in which the through hole 10 is provided in the substrate 6 have been described, but the present invention will not be limited thereto. In Modification 2, an example of a semiconductor device 120 in which the through hole is provided in the casing 1 will be described.

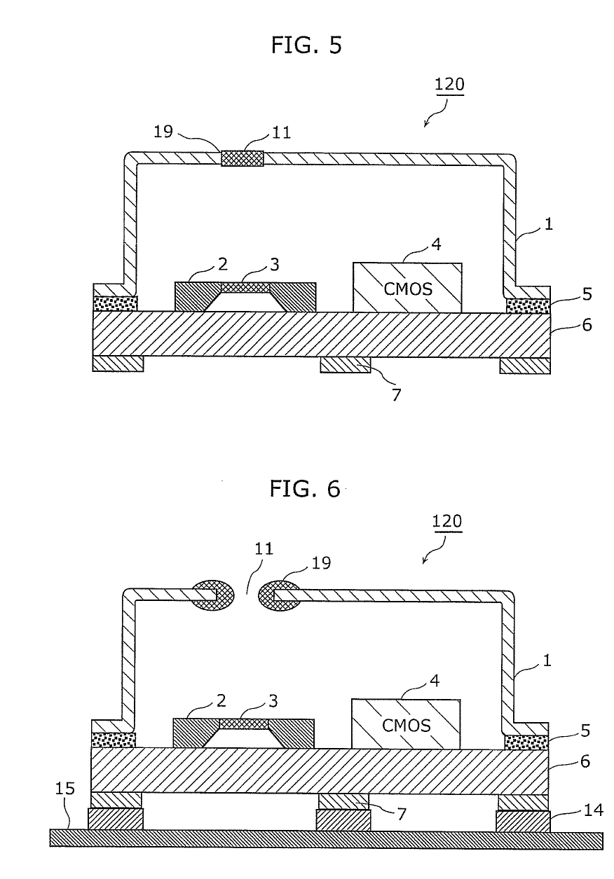

FIG. 5 is a sectional view of a semiconductor device according to Modification 2 of Embodiment 1. FIG. 6 is a sectional view of a mounted body on which the semiconductor device according to Modification 2 of Embodiment 1 is mounted. Same reference numerals will be given to the same elements as those in FIG. 1 or FIG. 2, and detailed description thereof will be omitted.

Unlike the semiconductor device 100 in which the through hole 10 is formed in the substrate 6, the semiconductor device 120 shown in FIG. 5 and FIG. 6 has a through hole 11 in a casing 1.

The casing 1 has the through hole 11 formed therein, and is surface treated. Preferably, the casing 1 in the vicinity of the through hole 11 is surface treated by Au/Ni.

As shown in FIG. 5, the through hole 11 is formed in the casing 1, and is filled (closed) by filling the through hole with a filling substance 19 at a thickness equal to or not more than that of the casing 1.

As shown in FIG. 6, the through hole 11 is filled with the filling substance 19. The filling substance 19 is molten by heating of a solder 14 when the semiconductor device 120 is mounted on a mother substrate 15, to wettably spread around the through hole 11 in the casing 1. Thereby, the through hole 11 is opened.

Thus, the filling substance 19 wettably spreads around the through hole 11 in the casing 1 without contacting a substrate 6 and a semiconductor element 2 and semiconductor element 4 fixed to the substrate 6, as shown in FIG. 6.

For example, the filling substance 19 may be a substance having a melting point of not more than 260° C., or may be an Sn—Ag—Cu, Sn—Ag, Sn—Pb, or Sn—Bi solder. The filling substance 19 may also be the filling substance 9 described above. Namely, the filling substance 19 may be a substance having a melting point less than 220° C., a substance having a softening temperature less than 220° C., or a substance having a volatilizing temperature less than 220° C. The filling substance 19 may be any substance that is composed of a component different from the main component of the casing 1 or the main component of the surface plating in the casing 1, and melts, softens, or volatilizes at a temperature not more than the melting point of the solder.

Thus, the semiconductor device 110 is configured, and mounted on the mother substrate 15 by the solder 14.

As above, according to Modification 2, the through hole 11 is provided in the casing 1. Thereby, when the semiconductor device 120 is mounted on the mother substrate 15, the filling substance 19 can wettably spread around the through hole 11 in the casing 1 to open the through hole 11, without contacting the substrate 6 and the semiconductor element 2 and semiconductor element 4 fixed to the substrate 6.

### Embodiment 2

In Embodiment 1, an example in the case where the through hole formed in the semiconductor device is filled with a substance having a melting point lower than that of the solder has been described, but the present invention will not be limited thereto. Hereinafter, as Embodiment 2, an example in which a moisture absorbable substance is provided in the through hole formed in the semiconductor device will be described.

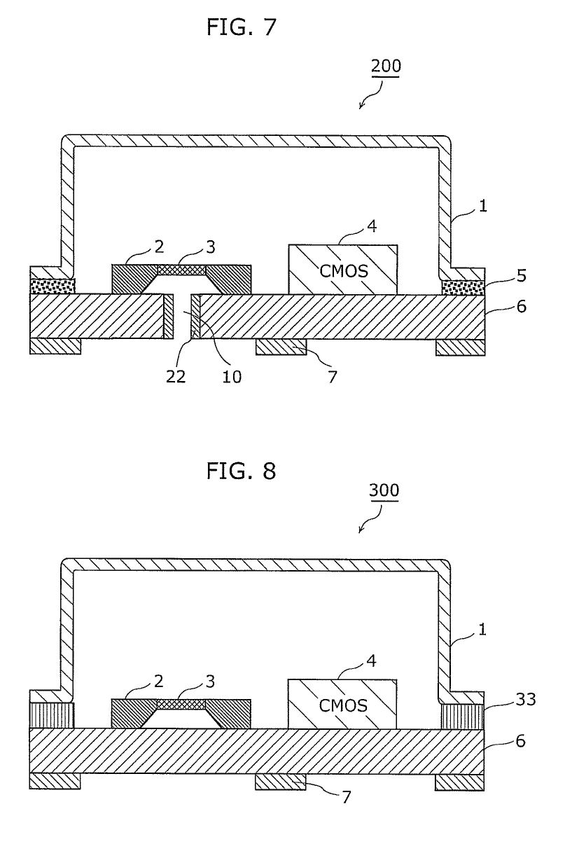

FIG. 7 is a sectional view of a semiconductor device according to Embodiment 2. Same reference numerals will be given to the same elements as those in FIG. 1, and detailed description thereof will be omitted.

Unlike the semiconductor device 100 in which the through hole 10 is filled with the filling substance 9, the semiconductor device 200 shown in FIG. 7 includes a highly moisture absorbable substance 22.

A through hole 10 is formed in a substrate 6. On the inner wall of the through hole 10, a highly moisture absorbable substance 22 is provided.

The moisture absorbable substance 22 is provided in order to prevent intrusion of the cutting water into the semiconductor device 200 during the dicing process when the semiconductor devices 200 simultaneously formed are separated into pieces or singulated by the dicing or the process method of cutting with a metal mold.

The moisture absorbable substance 22 has high moisture absorbing properties such as a high moisture absorbing rate and a moisture absorbing speed, and is composed of a fiber material, for example. The moisture absorbable substance 22 is not limited to the substance composed of the fiber material, and may be a substance composed of one of silicon dioxide (SiO₂), calcium oxide (CaO), alumina (Al₂O₃), and calcium chloride (CaCl₂).

As shown in FIG. 7, the moisture absorbable substance 22 does not close the through hole 10 even after the moisture absorbable substance 22 is provided on the inner wall of the through hole 10. The moisture absorbable substance 22 does not close the through hole 10 so as to keep the through hole 10 opened even after the moisture absorbable substance 22 absorbs moisture in the singulation of the semiconductor device 200.

Thus, the semiconductor device 200 is configured.

As above, according to Embodiment 2, a highly moisture absorbable substance 22 is provided on the inner wall of the through hole 10 in the semiconductor device 200. Thereby, no cutting water and cutting wastes enter the through hole 10, and the diaphragm structure 3 can be protected.

This can provide a semiconductor device in which intrusion of the cutting water and cutting wastes during the singulation process can be prevented, and reliability is improved.

In the description, the through hole 10 is provided in the substrate 6, but not limited thereto. The through hole 10 may be provided in the casing 1. In this case, the moisture absorbable substance 22 may be provided on the inner wall of the through hole 10 in the casing 1.

### Embodiment 3

In Embodiments 1 and 2, the examples in the case where the through hole is formed in the substrate of the semiconductor device or the casing have been described, but the present invention will not be limited thereto. Hereinafter, as Embodiment 3, an example of other aspect of the through hole formed in the semiconductor device will be described.

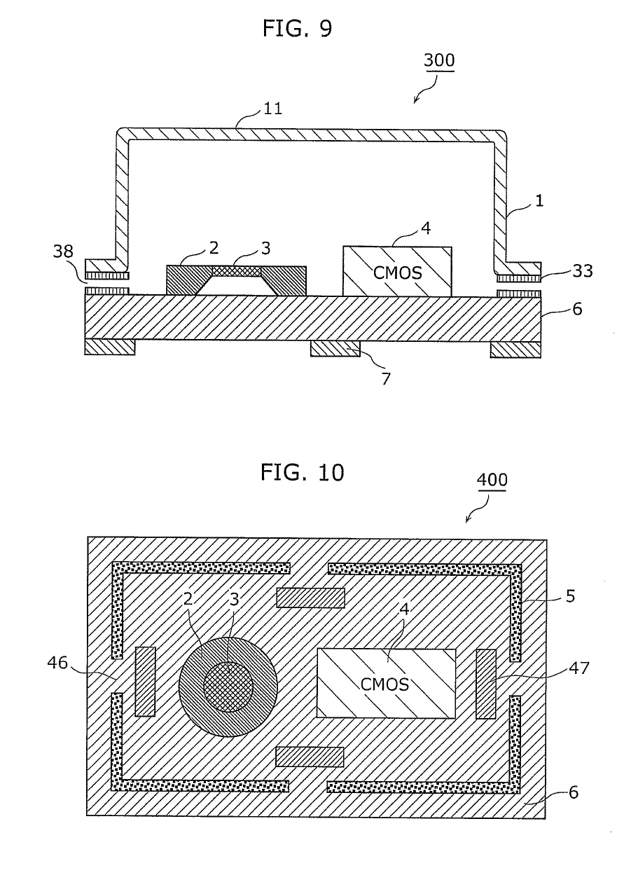

FIG. 8 is a sectional view of a semiconductor device according to Embodiment 3. FIG. 9 is a sectional view of a mounted body on which the semiconductor device according to Embodiment 3 is mounted. Same reference numerals will be given to the same elements as those in FIG. 1 or FIG. 2, and detailed description thereof will be omitted.

Unlike the semiconductor device 100 in which the through hole 10 is formed in the substrate 6, the semiconductor device 300 shown in FIG. 8 and FIG. 9 includes a through hole 38 formed in an adhesive substance 33 used to fix a casing 1 to a substrate 6 instead of the through hole formed in the substrate 6.

In the semiconductor device 300, the casing 1 is fixed to the substrate 6 by the adhesive substance 33.

The adhesive substance 33 fixes the casing 1 to the substrate 6 as shown in FIG. 8. The adhesive substance 33 has unique properties as follows. Before the semiconductor device 300 is mounted on a mother substrate 15, the adhesive substance 33 temporarily fixes the casing 1 to the substrate 6 to seal the space defined by the casing 1 and the substrate 6. By the heat during mounting on the mother substrate 15, a through hole penetrating from the inside to the outside of the space defined by the casing 1 and the substrate 6 is formed in the adhesive substance 33, as shown in FIG. 9. The through hole functions as the through hole 38.

For this reason, in the semiconductor device 300, no cutting water during the dicing and cutting wastes during the metal mold process enter the space defined by the casing 1 and the substrate 6, and a fragile diaphragm structure 3 is not broken.

Here, the adhesive substance 33 may be a solder paste that produces a large amount of voids, or a substance that becomes porous by heating, for example.

The through hole 38 to be formed after the semiconductor device 300 is mounted on a mother substrate 15 may be formed in any portion of the adhesive substance 33 that bonds the casing 1 to the substrate 6, but not in a specific portion thereof.

Thus, the semiconductor device 300 is configured, and mounted on the mother substrate 15 by a solder 14.

As above, according to Embodiment 3, if the adhesive substance 33 is used as an adhesive for fixing the casing 1 to the substrate 6, the microphone semiconductor device 300 is mounted on the mother substrate 15, and subsequently the through hole 38 is formed in the adhesive substance 33 by heat. Thereby, no through hole needs to be individually provided in the substrate 6 or the casing 1, therefore leading to reduction in manufacturing cost. Thus, a semiconductor device can be provided in which intrusion of the cutting water and cutting wastes during the singulation process can be prevented, and reliability is improved.

### Embodiment 4

In Embodiment 4, as other aspect of Embodiment 3, an example using a gap formed by partially applying an adhesive will be described.

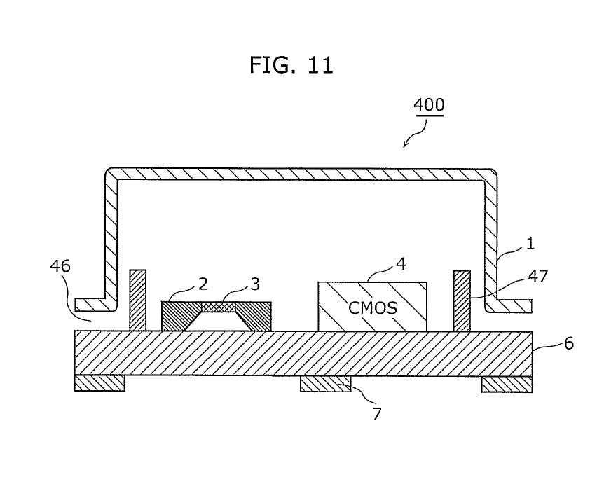

FIG. 10 is a top view of a semiconductor device according to Embodiment 4. FIG. 11 is a sectional view of a semiconductor device according to Embodiment 4. Same reference numerals will be given to the same elements as those in FIG. FIG. 8 or FIG. 9, and detailed description thereof will be omitted.

Unlike the semiconductor device 300 in which the through hole 38 is formed in the adhesive substance 33 used to fix the casing 1 to the substrate 6, the semiconductor device 400 shown in FIG. 10 and FIG. 11 includes a gap 46 and a dam 47 that are formed in advance.

As shown in FIG. 10, in order to fix a casing 1 to a substrate 6, an adhesive 5 is applied to a periphery of a region on a substrate 6 on which a semiconductor element 2 having a diaphragm structure 3 and a semiconductor element 4 are mounted. At least one gap 46 without the adhesive is provided in part of the periphery of the region to which the adhesive 5 is applied.

The gap 46 is the part of the periphery of the region on the substrate 6, and is a portion to which the adhesive 5 is not applied.

The dam 47 is at least one dam formed at a predetermined distance from the gap 46 in the adhesive 5 so as to be wider than the width of the gap 46. The dam 47 is formed between the gap 46 and the semiconductor element 2 and/or between the gap 46 and the semiconductor element 4, and for example, formed on the substrate 6 on a straight line between the gap 46 and the semiconductor element 2 or semiconductor element 4 in the vicinity of the gap 46. The area of the dam 47 is desirably larger than that of the cross section of the gap 46.

The dam 47 may be formed with a material containing a resin component, or a highly moisture absorbable material, for example, one of the inorganic substances such as silicon dioxide (SiO₂), calcium oxide (CaO), alumina (Al₂O₃), and calcium chloride (CaCl₂).

Thus, the semiconductor device 400 is configured.

As shown in FIG. 11, in the semiconductor device 400, the casing 1 is mounted on the substrate 6, and the adhesive 5 is cured thereby to fix the casing 1 to the substrate 6.

After the casing 1 is fixed to the substrate 6, the gap 46 serves an opening between the casing 1 and the substrate 6, and penetrates from the inside to the outside of the space defined by the casing 1 and the substrate 6. The opening formed with the gap 46 may also be used as a sound hole (through hole). In this case, no through hole needs to be provided in the casing 1 or the substrate 6, therefore leading to reduction in manufacturing cost.

According to the above configuration, in the semiconductor device 400, the adhesive 5 for fixing the casing 1 to the substrate 6 is provided with the opening formed with the gap 46. The dam 47 is formed a predetermined distance from the opening. The dam 47 can prevent intrusion of the cutting water during the dicing and cutting wastes during the metal mold process.

### Embodiment 5

In Embodiments 1 to 4, an example has been described in which the casing 1 is used as an object that covers the semiconductor element 2 and semiconductor element 4 fixed to the substrate of the semiconductor device (a shield cap), but the present invention will not be limited thereto. For example, a rib and a plate cap may be used instead of the casing 1. Hereinafter, as Embodiment 5, an example in the case of using a rib and a plate cap will be described.

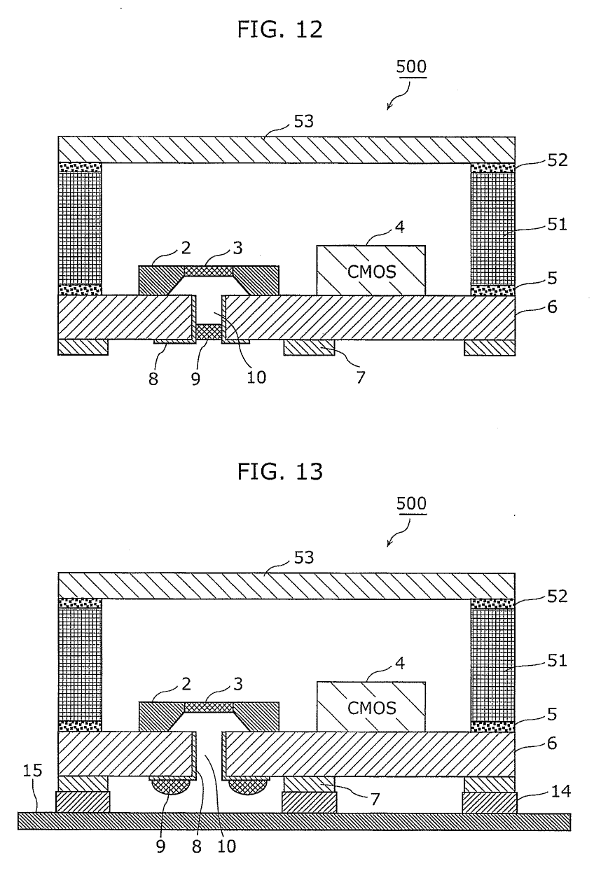

FIG. 12 is a sectional view of a semiconductor device according to Embodiment 5. FIG. 13 is a sectional view of a mounted body on which the semiconductor device according to Embodiment 5 is mounted. Same reference numerals will be given to the same elements as those in FIG. 1 or FIG. 2, and detailed description thereof will be omitted.

Unlike the semiconductor device 100, in the semiconductor device 500 shown in FIG. 12, instead of the casing 1, a combination of a rib 51 and a plate cap 53 is fixed to a substrate 6 by an adhesive 5.

The combination of the rib 51 and the plate cap 53 covers a semiconductor element 2 and semiconductor element 4 fixed to the substrate 6, and is fixed to the substrate 6 by the adhesive 5.

The rib 51 is provided on the top surface of the substrate 6 so as to surround the semiconductor element 2 and the semiconductor element 4, and is fixed to the substrate 6 by the adhesive 5.

The plate cap 53 is a flat plate. The plate cap 53 is provided on the rib 51 so as to cover the semiconductor element 2 and semiconductor element 4 fixed to the substrate 6, and is fixed to the rib 51 by an adhesive 52.

The adhesive 5 and the adhesive 52 are cured by heat (thermally cured) after the rib 51 and the plate cap 53 are provided. Thereby, the adhesive 5 fixes the substrate 6 to the rib 51, and the adhesive 52 fixes the rib 51 to the plate cap 53.

Thus, the semiconductor device 500 is configured.

As shown in FIG. 13, the semiconductor device 500 is mounted on a mother substrate 15 by a solder 14. The aspect of the mounted body on which the semiconductor device 500 is mounted is the same as that in FIG. 2, and the description thereof will be omitted.

Next, a manufacturing method will be described using the semiconductor device 500 as an example.

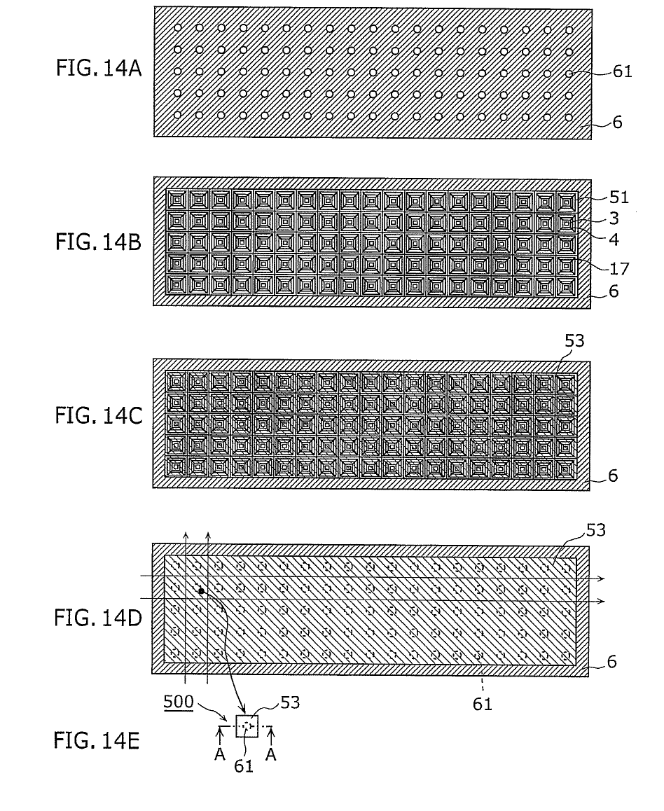

FIG. 14 is a drawing for illustrating a method for manufacturing a semiconductor device according to Embodiment 5.

First, a through hole 61 is provided in a substrate 6 (FIG. 14A, and the through hole 61 is filled with a substance having a melting point lower than that of the solder. A semiconductor element 2 having a diaphragm structure 3 and a semiconductor element 4 separately formed are fixed to a substrate 6. For connection to an electrode 7 to be formed later, the semiconductor element 2 and the semiconductor element 4 are electrically connected to a bonding pad 17 provided in the substrate 6. Subsequently, a rib 51 is provided on the top surface of the substrate 6 so as to surround the semiconductor element 2 and the semiconductor element 4, and the rib 51 is fixed by an adhesive 5 (FIG. 14B). The drawing shows an example in which a plurality of semiconductor elements 2 and a plurality of semiconductor elements 4 are fixed to the substrate 6. The rib 51 is provided so as to surround the semiconductor element 2 and the semiconductor element 4.

Next, a plate cap 53 is provided on the rib 51 so as to cover the semiconductor element 2 and semiconductor element 4 fixed to the substrate 6, and is fixed to the rib 51 by an adhesive 52. Subsequently, the adhesive 5 and the adhesive 52 each are thermally cured. Thereby, the rib 51 is fixed to the substrate 6 by the adhesive 5, and the plate cap 53 is fixed to the rib 51 by the adhesive 52 (FIG. 14C).

Next, the substrate 6 is simultaneously cut by a dicing blade, for example, (FIG. 14D) to singulate the semiconductor device 500 (FIG. 14E). Here, the through hole 61 provided in the substrate 6 is filled with a substance having a melting point lower than that of the solder. Accordingly, no cutting wastes and cutting water during the separation for singulation of the semiconductor device 500 enter the through hole.

Thus, the semiconductor device 500 is manufactured.

As above, Embodiment 5 can provide a semiconductor device in which intrusion of the cutting water and cutting wastes during the singulation process can be prevented, and reliability is improved.

As described above, a plurality of semiconductor devices 500 is formed in batch, and singulated later, thereby enabling simplification of the step and reduction in manufacturing cost.

### Modifications

In Embodiment 5, an example of the semiconductor device 500 in which the through hole 10 is provided in the substrate 6 has been described, but the present invention will not be limited thereto. Similarly, in each of the semiconductor devices according to Embodiment 1 to 4, the casing 1 may be replaced by the rib 51 and the plate cap 53.

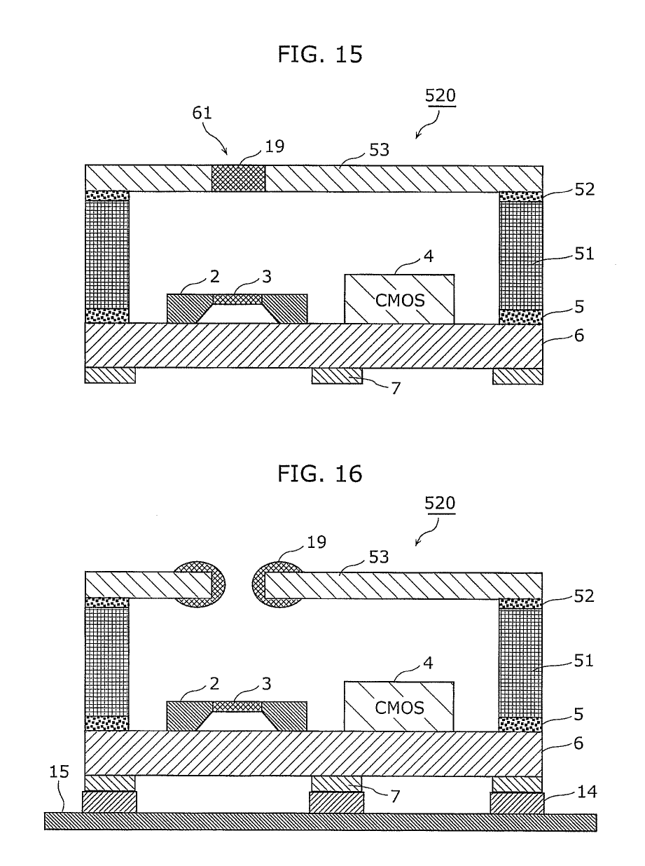

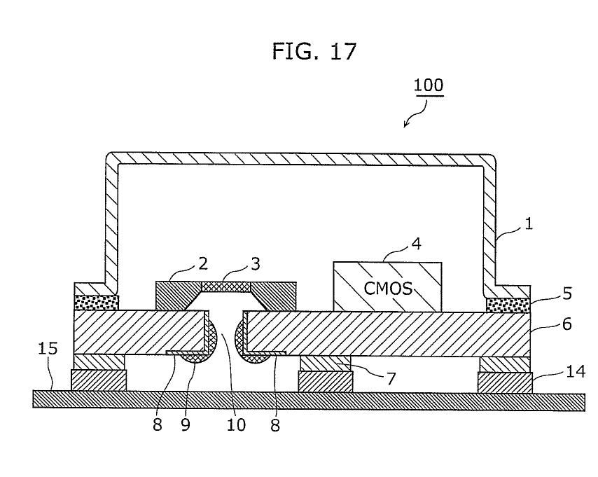

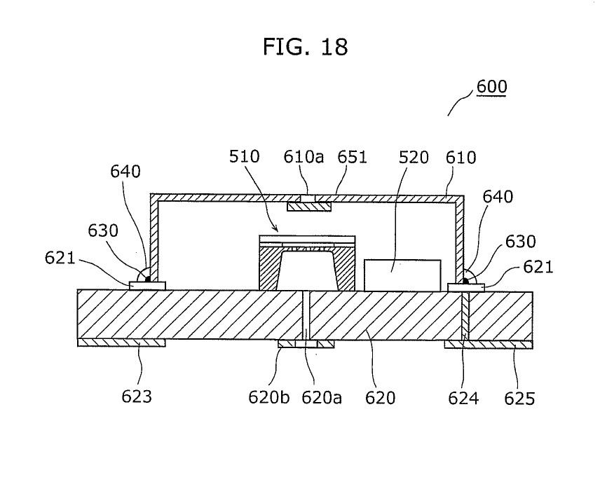

As an example, a semiconductor device 520 will be shown in FIG. 15 and FIG. 16 in which the casing 1 of the semiconductor device 120 according to Modification 2 of Embodiment 1 is replaced by the rib 51 and the plate cap 53.

FIG. 15 is a sectional view of other aspect of the semiconductor device according to Embodiment 5. FIG. 16 is a sectional view of a mounted body on which the semiconductor device shown in FIG. 15 is mounted. Same reference numerals will be given to the same elements as those in FIG. 1, FIG. 2, FIG. 12 and FIG. 13, and detailed description thereof will be omitted.

As shown in FIG. 15, a through hole 61 is formed in a plate cap 53, and filled with a filling substance 19 such that the thickness of the filling substance 19 may be equal to or not more than that of the plate cap 53. Thereby, the through hole 61 is closed.

As shown in FIG. 16, a through hole 61 is filled (closed) by filling the through hole with a filling substance 19. The filling substance 19 is molten by heating of a solder 14 when a semiconductor device 520 is mounted on a mother substrate 15, to wettably spread on a plate cap 53 around the through hole 61. Thereby, the through hole 61 is closed.

As above, the through hole 61 is provided in the plate cap 53. Thereby, when the semiconductor device 520 is mounted on the mother substrate 15, the filling substance 19 can wettably spread on the plate cap 53 around the through hole 61 without contacting the substrate 6 and the semiconductor element 2 and semiconductor element 4 fixed to the substrate 6, to open the through hole 61.

As described above, the semiconductor device according to the present invention can provide a semiconductor device in which intrusion of the cutting water and cutting wastes during the singulation process can be prevented, and reliability is improved.

Specifically, the semiconductor device according to the present invention is a semiconductor device including a substrate, at least one semiconductor element having a piezoelectric conversion function and mounted on the main surface of the substrate, a casing fixed to the main surface of the substrate to cover the semiconductor element, a through hole formed in the substrate or the casing, and a predetermined substance filled into the through hole to close the through hole, wherein the predetermined substance has properties such that the predetermined substance wettably spreads by heating to open the through hole. Thereby, a semiconductor device can be provided in which intrusion of the cutting water and cutting wastes during the singulation process can be prevented, and reliability is improved

An example in which the predetermined substance wettably spreads in the vicinity of the through hole by heating has been described, but the present invention will not be limited thereto. As shown in FIG. 17, the predetermined substance may wettably spread into the through hole. For example, the predetermined substance may wettably spread onto the inner wall of the through hole or a region in the main surface of the substrate that contacts the through hole.

The predetermined substance is not limited to the substance that wettably spreads by heating, and may be the moisture absorbable substance described above. In this case, the moisture absorbable substance may be provided on the inner wall of the through hole or the region in the main surface of the substrate that contacts the through hole, as described above.

As described above, the semiconductor device according to the present invention has been described on the basis of the embodiments, but the present invention will not be limited to these embodiments. A variety of modifications of the present embodiments conceived by persons skilled in the art without departing the scope of the present invention and embodiments in combination with components in different embodiments are also included within the scope of the present invention.

For example, a semiconductor mounted body in which the semiconductor device according to the present invention is mounted on a mother substrate is also included within the scope of the present invention. The semiconductor mounted body forms mobile phones and DSCs (Digital Still Cameras), for example.

### INDUSTRIAL APPLICABILITY

The present invention can be used for semiconductor devices, and particularly for semiconductor devices having an electret condenser with a vibrating electrode or a diaphragm structure.

What is claimed is:

1. A semiconductor device comprising:
a substrate;
at least one semiconductor element having a piezoelectric conversion function and mounted on a main surface of said substrate;
a casing fixed to the main surface of said substrate to cover said semiconductor element;
a through hole formed in one of said substrate and said casing; and
a predetermined substance filled into said through hole to close said through hole,
wherein said predetermined substance has properties such that said predetermined substance wettably spreads by heating to open said through hole.

2. A semiconductor device comprising:
a substrate;
at least one semiconductor element having a piezoelectric conversion function and mounted on a main surface of said substrate;
a casing fixed to the main surface of said substrate to cover said semiconductor element;
a through hole formed in one of said substrate and said casing; and
a predetermined substance wettably spread on said through hole or said substrate to open said through hole,
wherein said predetermined substance has properties such that said predetermined substance wettably spreads by heating.

3. The semiconductor device according to claim 1,
wherein said predetermined substance has a melting point less than 220° C., a softening temperature less than 220° C., or a volatilizing temperature less than 220° C.

4. The semiconductor device according to claim 1,
wherein an inner wall of said through hole and a portion around said through hole on a surface opposite to the main surface are metal-plated.

5. The semiconductor device according to claim 1,
wherein part of said substrate has a depression formed around said through hole on the surface opposite to the main surface.

6. A semiconductor device comprising:
a substrate;
at least one semiconductor element having a piezoelectric conversion function and mounted on the main surface of said substrate;
a casing fixed to the main surface of said substrate to cover said semiconductor element; and
a through hole formed in one of said substrate and said casing,
wherein a moisture absorbable substance having moisture absorbing properties is provided on an inner wall of said through hole.

7. The semiconductor device according to claim 6,
wherein the moisture absorbable substance is composed of one of a fiber material, silicon dioxide (SiO₂), calcium oxide (CaO), alumina (Al₂O₃), and calcium chloride (CaCl₂).

8. A semiconductor device comprising:
a substrate;
at least one semiconductor element having a piezoelectric conversion function and mounted on the main surface of said substrate;
a casing fixed to the main surface of said substrate to cover said semiconductor element; and
an adhesive applied to said substrate to fix said substrate to said casing in close contact and seal said semiconductor element;
wherein part of said adhesive is opened by heating.

9. The semiconductor device according to claim 8,
wherein said adhesive has a melting point less than 220° C., a softening temperature less than 220° C., or a volatilizing temperature less than 220° C.

10. A semiconductor device comprising:
a substrate;
at least one semiconductor element having a piezoelectric conversion function and mounted on the main surface of said substrate;
a casing fixed to the main surface of said substrate to cover said semiconductor element;
an adhesive applied to a periphery of a region of the main surface on which said semiconductor element is mounted, to fix said casing to said substrate in close contact; and
a dam having a height greater than a thickness of said adhesive and formed between said semiconductor element and said adhesive on the main surface of said substrate,
wherein at least one gap without said adhesive is provided in part of the periphery of the region to which said adhesive is applied,
said dam is formed between the at least one gap and said semiconductor element, and
said gap is configured to serve as a through hole after said substrate is fixed to said casing.

11. A semiconductor device comprising:
a substrate;
at least one semiconductor element having a piezoelectric conversion function and mounted on the main surface of said substrate;
a casing fixed to the main surface of said substrate to cover said semiconductor element; and
a through hole formed in one of said substrate and said casing,
wherein a substance having a melting point less than 220° C., a softening temperature less than 220° C., or a volatilizing temperature less than 220° C. is annularly formed on an inner wall of said through hole or an inner wall of said through hole on a side opposite to the main surface of said substrate.

12. A semiconductor device comprising:
a substrate;
at least one semiconductor element having a piezoelectric conversion function and mounted on the main surface of said substrate;
a rib fixed to the main surface of said substrate so as to surround said semiconductor element;
a plate cap that is a flat plate, and is fixed to said rib so as to cover said semiconductor element;
a through hole formed in said substrate or said plate cap; and
a predetermined substance filled into said through hole to close said through hole,
wherein said predetermined substance has properties such that said predetermined substance wettably spreads by heating to open said through hole.

13. The semiconductor device according to claim 2,
wherein said semiconductor device includes a plurality of electrodes formed on a surface opposite to the main surface of said substrate for connection to a mother substrate, and
said semiconductor device is mounted on a mother substrate, on which said semiconductor device is mounted, through the plurality of electrodes using a solder.

14. A semiconductor mounted body comprising:
a semiconductor device including a substrate; at least one semiconductor element having a piezoelectric conversion function and mounted on the main surface of said substrate; a casing fixed to the main surface of said substrate to cover said semiconductor element; and a through hole formed one of said substrate and said casing, wherein a moisture absorbable substance having moisture absorbing properties or a substance having properties such that the substance wettably spreads by heating is provided on an inner wall of said through hole or in a region of the main surface of said substrate that contacts said through hole;
an adhesive substance used to mount said semiconductor device to a mother substrate; and
said mother substrate.

15. A manufacturing method comprising:
forming a semiconductor device comprising a substrate; at least one semiconductor element having a piezoelectric conversion function and mounted on the main surface of said substrate; a casing fixed to the main surface of said substrate to cover said semiconductor element; and a through hole formed in the substrate or the casing;
filling a predetermined substance for closing the through hole into the through hole of the semiconductor device; and
wettably spreading the predetermined substance by heating to open the through hole.
